(19) United States
(12) Patent Application Publication
(10) Pub. No.: US 2023/0017350 A1
(43) Pub. Date: Jan. 19, 2023

(54) INDEPENDENT GATE CONTACTS FOR CFET

(71) Applicant: Tokyo Electron Limited, Tokyo (JP)

(72) Inventors: Daniel CHANEMOUGAME, Niskayuna, NY (US); Lars LIEBMANN, Mechanicsville, NY (US); Jeffrey SMITH, Clifton Park, NY (US); Paul GUTWIN, Williston, VT (US)

(73) Assignee: Tokyo Electron Limited, Tokyo (JP)

(21) Appl. No.: 17/836,019

(22) Filed: Jun. 9, 2022

Related U.S. Application Data
(60) Provisional application No. 63/222,275, filed on Jul. 15, 2021.

(51) Int. Cl. H01L 21/8238; H01L 27/092; H01L 23/535; H01L 29/06; H01L 29/423; H01L 29/786; H01L 21/02; H01L 21/768; H01L 21/822; H01L 29/66

(52) U.S. Cl. CPC H01L 21/823871; H01L 27/0922; H01L 23/535; H01L 29/0673; H01L 29/42392; H01L 29/78696; H01L 21/02603; H01L 21/76897; H01L 21/8221; H01L 21/823807; H01L 29/66742

(57) ABSTRACT

Aspects of the present disclosure provide a method of manufacturing a three-dimensional (3D) semiconductor device. For example, the method can include forming a target structure, the target structure including a lower gate region, an upper gate region, and a separation layer disposed between and separating the lower gate region and the upper gate region. The method can also include forming a sacrificial contact structure extending vertically from the bottom gate region through the separation layer and the upper gate region to a position above the upper gate region, removing at least a portion of the sacrificial contact structure resulting in a lower gate contact opening extending from the position above the upper gate region to the bottom gate region, insulating a side wall surface of the lower gate contact opening, and filling the lower gate contact opening with a conductor to form a lower gate contact.

### INCORPORATION BY REFERENCE

This present disclosure claims the benefit of U.S. Provisional Application No. 63/222,275, entitled “INDEPENDENT GATE CONTACTS FOR CFET” filed on Jul. 15, 2021, which is incorporated herein by reference in its entirety.

### FIELD OF THE PRESENT DISCLOSURE

The present disclosure relates generally to microelectronic devices including semiconductor devices, transistors, and integrated circuits, including methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

Aspects of the present disclosure provide a method of manufacturing a three-dimensional (3D) semiconductor device. For example, the method can include forming a target structure, the target structure including a lower gate region, an upper gate region, and a separation layer disposed between and separating the lower gate region and the upper gate region. The method can also include forming a sacrificial contact structure extending vertically from the lower gate region through the separation layer and the upper gate region to a position above the upper gate region, removing at least a portion of the sacrificial contact structure resulting in a lower gate contact opening extending from the position above the upper gate region to the lower gate region, insulating a side wall surface of the lower gate contact opening, and filling the lower gate contact opening with a conductor to form a lower gate contact. In an embodiment, the method can further include depositing a lower gate stack material and an upper gate stack material in the lower gate region and the upper gate region, respectively.

In an embodiment, the method can further include forming an upper gate contact connected to the upper gate region. For example, the upper gate contact and the lower gate contact can be independent from each other. In another embodiment, the method can further include forming an upper electrical connection connected to the upper gate contact, and a lower electrical connection connected to the lower gate contact. For example, the upper gate contact, the upper electrical connection and the lower electrical connection can be formed in a dual damascene process. As another example, the lower electrical connection and the upper electrical connection can be independent from each other.

In an embodiment, depositing an upper gate stack material and a lower gate stack material is performed prior to removing at least a portion of the sacrificial contact structure. In another embodiment, the method, prior to removing at least a portion of the sacrificial contact structure, can further include performing a self-aligned-contact (SAC) process to form an SAC cap to cover the upper gate region. In another embodiment, the method, prior to insulating a side wall surface of the lower gate contact opening, can further include performing an isotropic etch to uncover the lower gate stack material of the lower gate region, wherein insulating a side wall surface of the lower gate contact opening includes insulating a side wall surface of the lower gate contact opening and the uncovered lower gate stack material of the lower gate region.

In an embodiment, removing a portion of the sacrificial contact structure is performed prior to depositing an upper gate stack material and a lower gate stack material. In another embodiment, filling the lower gate contact opening with a conductor can includes filling the lower gate contact opening with a sacrificial contact material, after depositing an upper gate stack material and a lower gate stack material is performed, removing the sacrificial contact material resulting in the lower gate contact opening, and filling the lower gate contact opening with the conductor to form the lower gate contact.

In an embodiment, the lower gate region can be a part of an n-type or p-type field effect transistor (FET), and the upper gate region can be a part of an n-type or p-type FET. In another embodiment, a bottom of the sacrificial contact structure can be below the lower gate region. In some other embodiments, a bottom of the sacrificial contact structure can be at a same level as the lower gate region. In various embodiments, the upper gate region can be vertically stacked on the lower gate region with the separation layer disposed therebetween.

Aspects of the present disclosure also provide a 3D semiconductor structure. For example, the 3D semiconductor structure can include an upper gate region, a lower gate region, a separation layer disposed between and separating the upper gate region and the lower gate region, an upper gate contact connecting the upper gate region to an upper electrical connection at a first location above the upper gate region, and a lower gate contact connecting the lower gate region to a lower electrical connection at a second location above the upper gate region, the lower gate contact extending through the upper gate region and being insulated from the upper gate region. In an embodiment, the lower gate contact and the upper gate contact can be independent from each other.

In an embodiment, the lower electrical connection and the upper electrical connection can be independent from each other. In another embodiment, the upper gate region can be vertically stacked on the lower gate region with the separation layer disposed therebetween. In some other embodiments, the lower gate region can be a part of an n-type or p-type field effect transistor (FET), and the upper gate region can be a part of an n-type or p-type FET.

[symbol]

Note that this summary section does not specify every embodiment and/or incrementally novel aspect of the present disclosure or claimed disclosure. Instead, this summary only provides a preliminary discussion of different embodiments and corresponding points of novelty over conventional techniques. For additional details and/or possible perspectives of the present disclosure and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1a illustrates a conventional, side by side, CMOS logic cell layout with shared, common N and P gates and with independent N and P gates;

FIG. 1b illustrates a cross section of the CMOS logic cell of FIG. 1a;

FIG. 2a illustrates a CFET CMOS logic cell with shared, common N and P gates, and with independent N and P gates;

FIG. 2b illustrates a cross section of the CFET CMOS logic cell of FIG. 2a;

FIG. 3a illustrates a “birds-eye-view” layout for a CFET CMOS logic cell in which both common and independent N & P gates are required in accordance with some embodiments of the present disclosure;

FIG. 3b illustrates a cross-sectional view along line A-A of the CFET CMOS logic cell of FIG. 3a;

FIG. 3c illustrates a cross-sectional view along line B-B of the CFET CMOS logic cell of FIG. 3a;

FIGS. 4a to 4f, 5a to 5e and 6a to 6d show cross-sectional substrate segments to illustrate methods herein to achieve a three-dimensional (3D) semiconductor structure that has independent gate contacts according to some embodiments of the present disclosure; and

FIGS. 7a to 7e and 8a to 8e show cross-sectional substrate segments to illustrate another methods herein to achieve a three-dimensional (3D) semiconductor structure that has independent gate contacts according to some embodiments of the present disclosure.

### DETAILED DESCRIPTION

The word “exemplary” is used herein to mean, “serving as an example, instance or illustration.” Any embodiment of construction, process, design, technique, etc., designated herein as exemplary is not necessarily to be construed as preferred or advantageous over other such embodiments. Particular quality or fitness of the examples indicated herein as exemplary is neither intended nor should be inferred.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the apparatus (or device) in use or operation in addition to the orientation depicted in the figures. The apparatus (or device) may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of the present disclosure, it is intended that each of the concepts can be executed independently of each other or in combination with each other. Accordingly, the present disclosure can be embodied and viewed in many different ways.

Techniques herein include simpler and more robust methods and final structures to enable independent lower and upper gates in stacked-device architectures such as CFET (complimentary field effect transistor with vertical channel stacking). Techniques herein provide methods and structures that provide CFET technology with beneficial features. One such feature is independently contacted lower and/or upper gates (or N & P, P & N, N & N or P & P), while also enabling common lower and upper (or N & P, P & N et cetera) gates. Process flows herein provide a unique final structure with simplified process and cost, and provide critical self-alignment between the first metal layer and this independent gate contacts construct.

Previous disclosure of inventors, U.S. Ser. No. 16/848,638 (Simultaneous Formation of Diffusion Break, Gate Cut, and Independent N And P Gates for 3D Transistor Devices), which is incorporated herein by reference in its entirety, describes techniques to obtain CMOS logic with a conventional integration scheme for conventional 2D designs, where N and P transistors are placed side by side, and share a common gate to achieve the CMOS complementary function. While this technique applies to a majority of devices, there are some critical logic cells that require the N and P gates to be independent from each other.

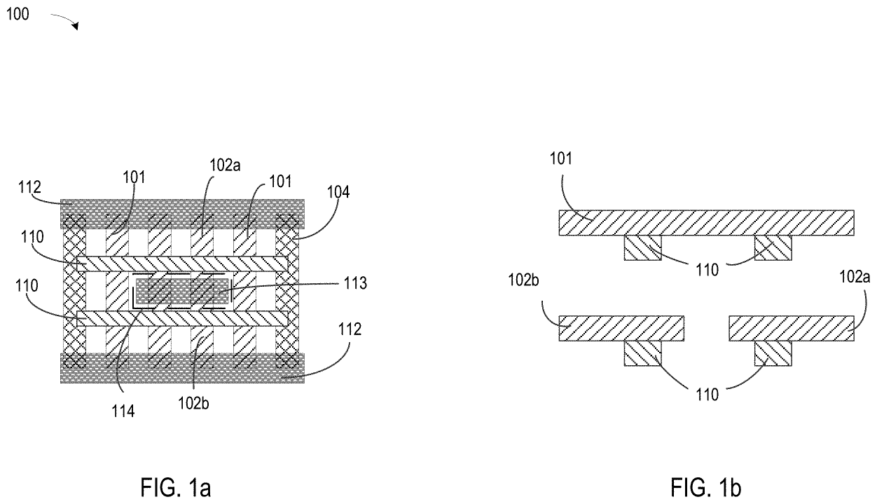

FIGS. 1a and 1b show a conventional CMOS logic cell 100 with shared, common N/P gates 101, and with independent N/P gates 102a/102b. The CMOS logic cell 100 further includes dummy gates 104, lateral cuts 112, a poly cut 113, and active layers 110. This functionality enables significant design scaling capability, and is therefore critical for advanced technology logic designs. With such 2D designs, it is straightforward to separate the independent N/P gates 102a/102b. The poly cut 113 is used to disconnect the N/P gates 102a/102b where needed, typically in the middle of the CMOS logic cell 100, in an N/P separation space 114.

In a CFET device, providing this functionality is more complex because the n-type and p-type semiconductor devices and their gates are on top of each other, no longer side by side. Accordingly, the N/P separation space 114 must now be made in the vertical plane instead of the horizontal plane, and the lower and upper gates need to be contacted independently from the top by the local interconnects. This can apply to N over P, P over N, N over N and P over P configurations, and therefore to SRAM designs as well.

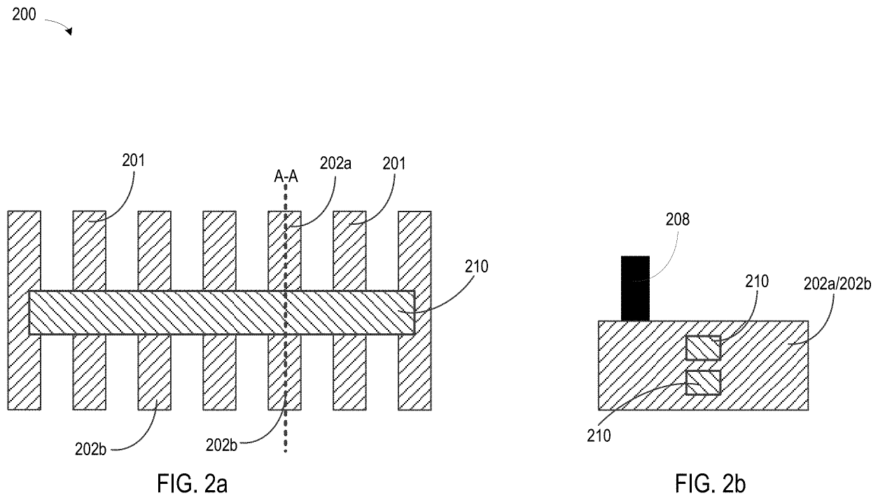

FIG. 2a is a diagram of a CFET CMOS logic cell 200 with shared, common N/P gates 201, and with independent N/P gates 202a/202b. FIG. 2b shows a cross section along A-A illustrating the inherent difficulty to achieve this in a CFET. As discovered herein, there are two main problems. One problem is how to electrically separate the N/P gates 202a/202b from each other. Another problem is how to connect the N/P gates 202a/202b independently and robustly to their respective gate contacts. These two issues must be solved with the minimum complexity to enable this functionality while reaching a reasonable and competitive process cost.

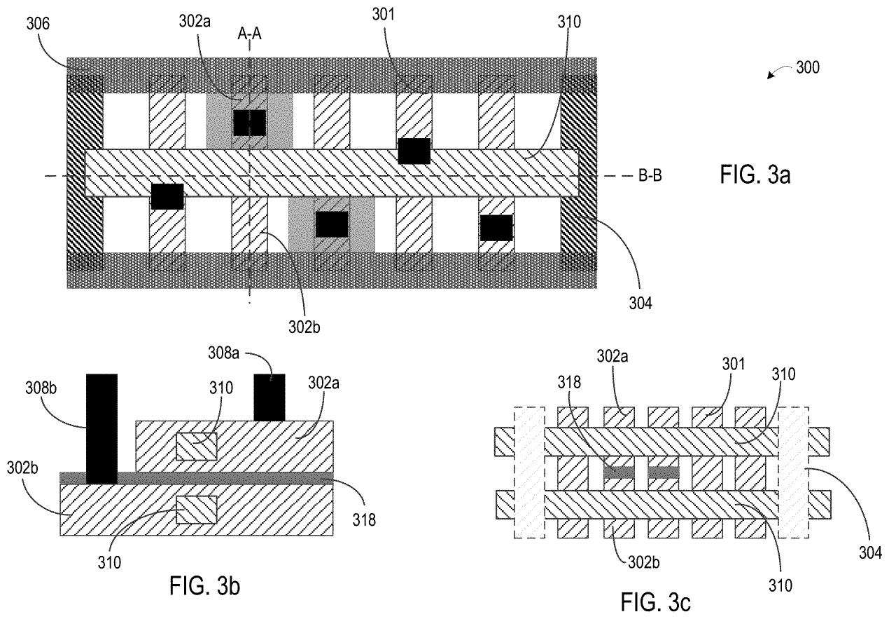

FIG. 3a is a top view layout of a CFET CMOS logic cell 300. FIG. 3b shows a cross section along A-A showing the final structure of the independent, isolated upper/lower (or N/P) gates 302a/302b with a separation layer 318 (e.g., a dielectric layer) disposed therebetween, and their respective upper/lower gate contacts 308a/308b. Poly terminations (poly lateral cuts) 306 can also be seen. FIG. 3c is a cross section along B-B showing the shared, common gates 301 and the independent N/P gates 302a/302b as well as diffusion breaks 304 at the cell boundaries. Aspects of U.S. Ser. No. 16/848,638 cover this part describing a method to realize a final structure indicated in FIG. 3b. In the case of CFET, the final structure looks like a staircase, where the lower gate contact 308b can be etched from the metal levels above (like M0, not shown), following a dual damascene process, to land on the lower gate 302b without interfering with the upper gate 302a.

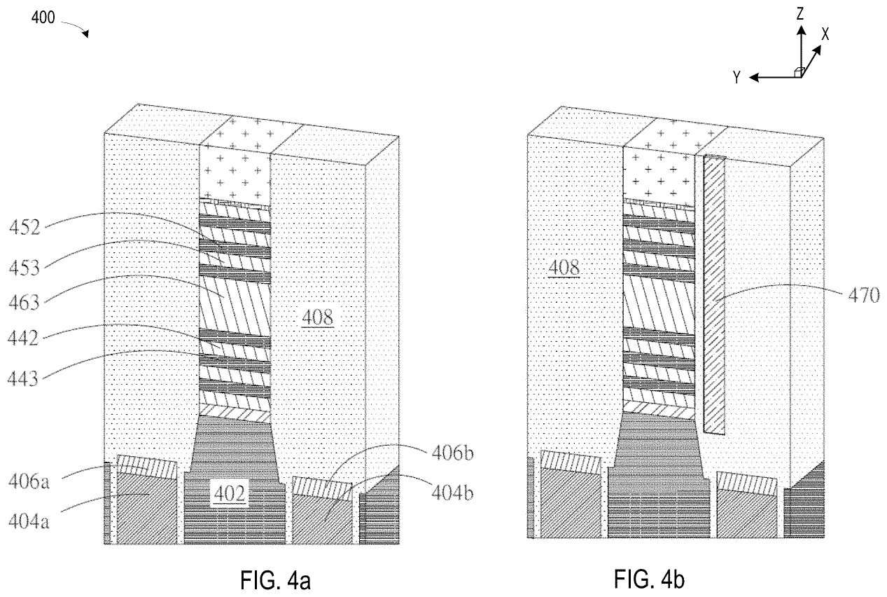

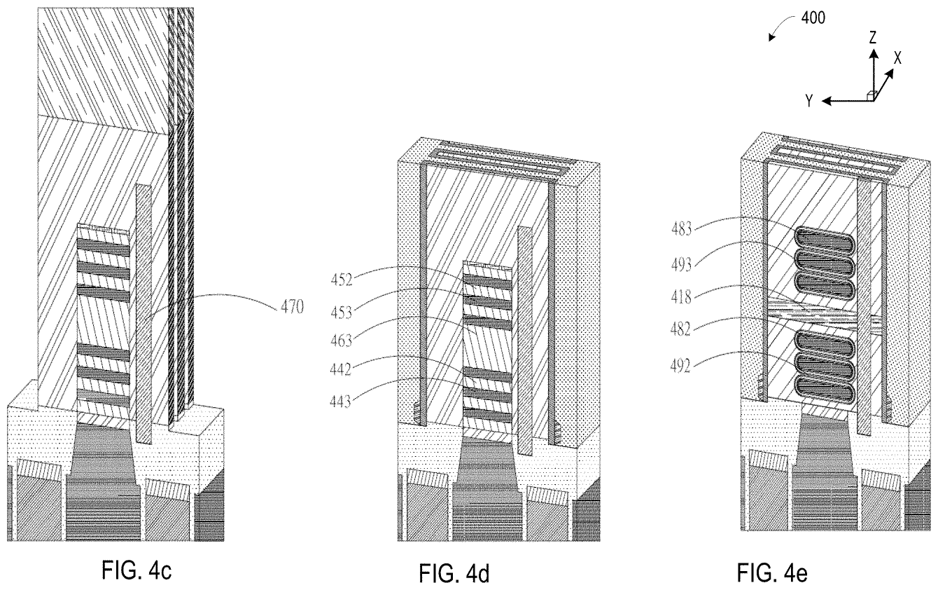

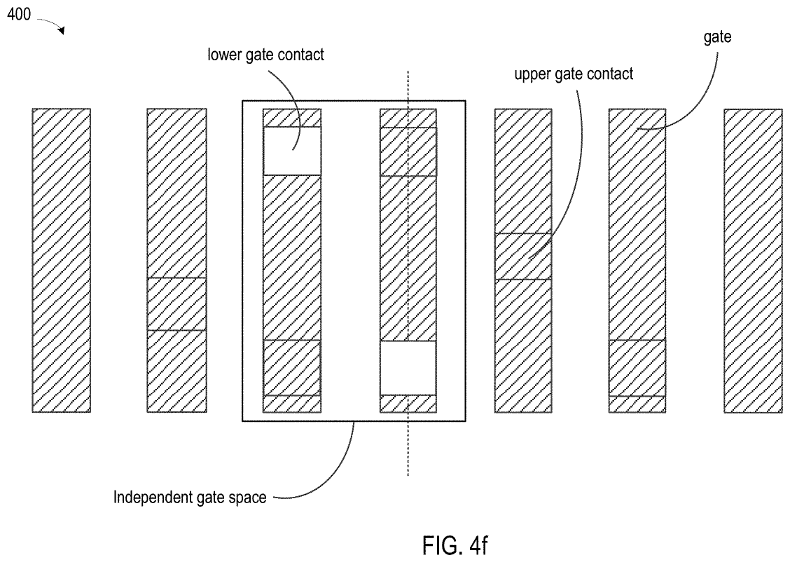

Techniques disclosed herein describe how to achieve independent gate contacts for CFET. FIGS. 4a to 4f, 5a to 5e and 6a to 6d show cross-sectional substrate segments to illustrate methods herein to achieve a three-dimensional (3D) semiconductor structure 400 that has independent gate contacts according to some embodiments of the present disclosure. FIGS. 4a to 4e show formation of a vertical element (or a sacrificial contact structure) of the semiconductor structure 400 in accordance with some embodiments of the present disclosure.

As shown in FIG. 4a, the semiconductor structure 400 can have a plurality of fin structures 402 protruding from a substrate (not shown) of a wafer. For example, one fin structure 402 is included in FIG. 4a. A plurality of buried power rail (BPR) structures 404a and 404b that are filled with a replacement BPR material can be arranged over the substrate and positioned between the fin structures 402. For example, the BPR structure 404b is positioned between the fin structure 402 shown in FIG. 4a and another fin structure (not shown) positioned at a right-hand side of the BPR structure 404b. The BPR structures 404a and 404b are buried at a bottom portion of the semiconductor structure 400. In some embodiments, the BPR structures 404a and 404b are filled with some type of replacement BPR material that can withstand the high thermal processing conditions in the front-end-of-line (FEOL) such as polysilicon or amorphous silicon. It should be understood that any number of BPR structures 404a and 404b can be formed to meet specific design requirements. Additionally, a plurality of dielectric caps 406a and 406b are positioned on the BPR structures 404a and 404b, respectively, and function as isolation layers.

Still referring to FIG. 4a, a first (or lower) channel structure 442 can be positioned over the fin structure 402. The lower channel structure 442 can include one or more first (or lower) nanosheets or nanowires. The lower nanosheets or nanowires can be stacked over the fin structure 402 and spaced apart from one another by a lower insulating layer 443. In an embodiment of FIG. 4a, the lower channel structure 442 includes three lower nanosheets.

Further, a second (or upper) channel structure 452 can be positioned over the lower channel structure 442. The upper channel structure 452 can also include one or more second (or upper) nanosheets or nanowires. The upper nanosheets or nanowires can be stacked over the lower channel structure 442 and spaced apart from one another by an upper insulating layer 453, which can be the same or different from the lower insulating layer 443. In an embodiment of FIG. 4a, the upper channel structure 452 also includes three upper nanosheets, and is spaced apart from the lower channel structure 442 by an insulating layer 463, which can be the same or different from the lower insulating layer 443 and/or the upper insulating layer 453. In addition, an insulating layer 408 (e.g., silicon oxide) can be deposited to cover the dielectric caps 406a and 406b, the BPR structures 404a and 404b, the fin structure 402 and the target structure.

As shown in FIG. 4b, a vertical element (or a sacrificial contact structure) 470 of the semiconductor structure 400 can be formed. For example, a lower gate contact opening can be patterned and partially transferred down into the insulating layer 408 through an etching process, and is filled with a low-K material such as SiOC, forming the vertical element 470, which is used to form a lower gate contact of the semiconductor structure 400. In the example embodiment, the bottom of the vertical element 470 is below the lower channel structure 442. In some other embodiments, the bottom of the vertical element 470 can be at the same level as the lower channel structure 442.

As shown in FIGS. 4c to 4e, a replacement metal gate (RMG) process is performed to form a lower source/drain (S/D) region 482, a lower gate region 492, an upper S/D region 483 and an upper gate region 493 of semiconductor structure 400. In the RMG process, the lower channel structure 442 and the upper channel structure 452 are generally comprised of boron-doped SiGe for p-type FETs and phosphorous and/or arsenic doped silicon for n-type FETs. The lower channel structure 442 and the upper channel structure 452 are then capped with a given dielectric etch-stop layer (CESL) to protect the silicon epitaxy surface from oxidation as well as to provide an etch-stop layer to prevent damage to the lower channel structure 442 and the upper channel structure 452. In the RMG process, lower work function metal and upper work function metal, which are etched-tuned to set various threshold voltages, are formed surrounding the lower channel structure 442 and the upper channel structure 452, respectively, to form the lower gate region 492 and the upper gate region 493, respectively. In the RMG process, a high-k dielectric film such as HfO or varieties of HfO coupled with dipole forming layers such as LaO and AlO, and a high-conductance metal can also be formed. One skilled in the arts will appreciate that many conventional intermediary steps are not shown for clarity and simplicity. Once the RMG process is completed, the vertical element 470 is in place. A dielectric separation layer 418 is also formed to separate an upper semiconductor device tier (including the upper S/D region 483 and upper gate region 493) and a lower semiconductor device tier (including the lower S/D region 482 and the lower gate region 492). The lower gate region 492, the upper gate region 493 and the separation layer 418 can be collectively referred to as a target structure.

FIG. 4F is a top view layout showing the lower and upper gate contacts and an independent gate space in a standard cell.

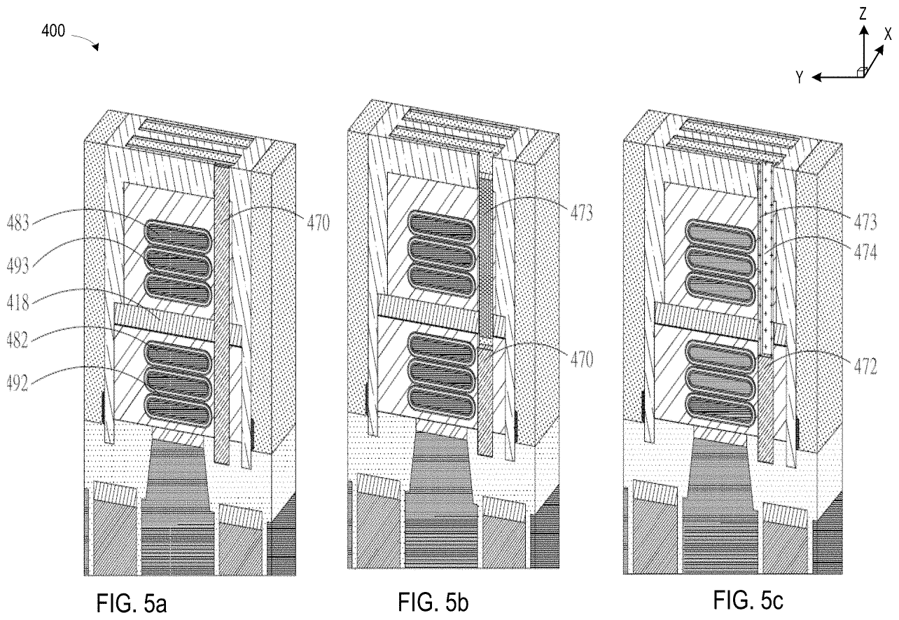

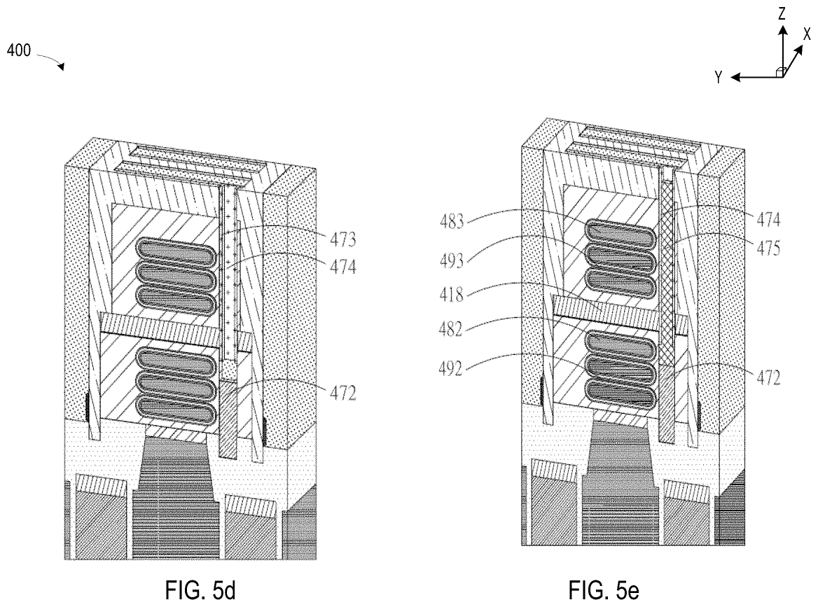

FIGS. 5a to 5e illustrate replacing a portion of the vertical element 470 by a final lower gate contact 475 in accordance with some embodiments of the present disclosure. As shown in FIG. 5a, a self-aligned-contact (SAC) process is performed. For example, the upper work function metal (i.e., an upper gate stack material) of the upper gate region 493 can be recessed, an etch stop layer such as SiN is filled in the recessed upper work function metal and planarized by chemical-mechanical polishing (CMP), and a protective dielectric layer such as silicon oxide is formed on the planarized etch stop layer to act as an SAC cap to cover and protect the upper gate region 493 from being electrically connecting the lower gate contact 472 during the formation of the lower gate contact 472. The vertical element 470 is not covered by the SAC cap.

As shown in FIG. 5b, the uncovered vertical element 470 is etched (dry or wet) partially until a top of the vertical element 470 is located at the same level as the lower gate region 492. In the embodiment where the bottom of the vertical element 470 is at the same level as the lower channel structure 442, the uncovered vertical element 470 can be etched completely. A cavity 473 thus formed is lined with an oxide spacer (i.e., a liner) 474, as shown in FIG. 5c. As shown in FIG. 5d, an isotropic etch (low-K) is performed to expose the lower work function metal of the lower gate region 492. As shown in FIG. 5e, the cavity 473 is filled with metal such as Al, Cu, W, Ru, Co, or other conductive materials to form the lower gate contact 475.

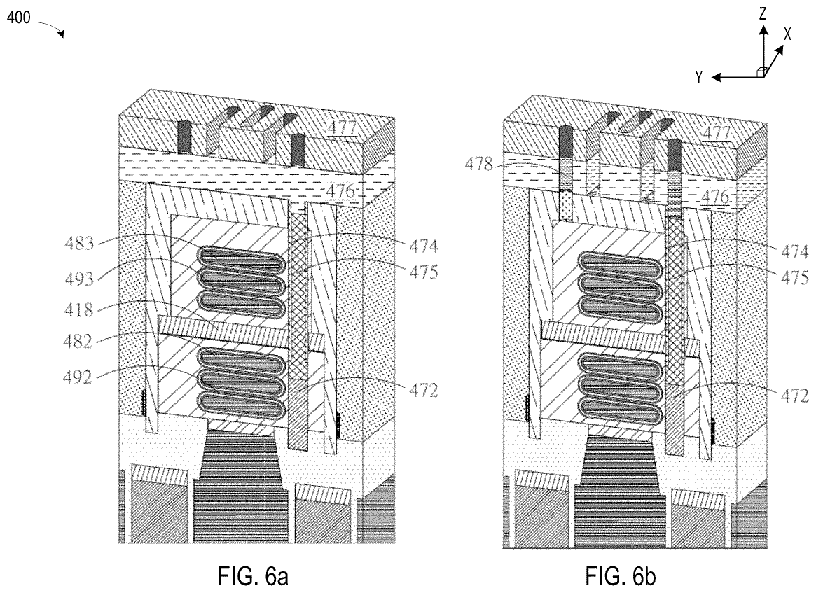

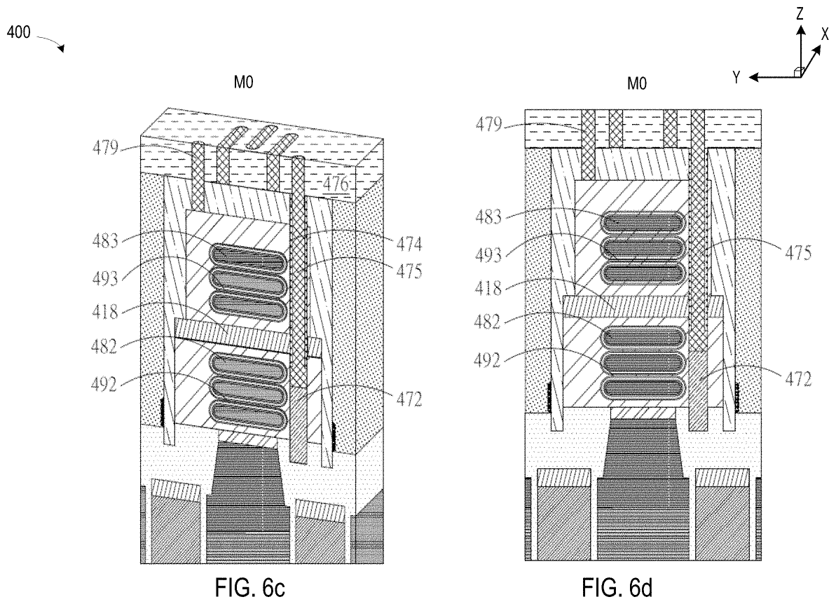

FIGS. 6a to 6d show a dual damascene process that is performed to connect the lower gate region 492 and the upper gate region 493 to the first metal layer (M0) in accordance with some embodiments of the present disclosure. As shown in FIG. 6a, a dielectric cap layer 476 is formed to cover the upper semiconductor device tier (including the upper S/D region 483 and upper gate region 493), and a resist (etch mask) 477 is patterned and formed on the dielectric cap layer 476. As shown in FIG. 6b, an etching process is performed to etch the dielectric cap layer 476 until uncovering the upper gate region 493 and the lower gate contact 475, which is connected to the lower gate contact 472, and cavities 478 are thus formed. As shown in FIG. 6c, the resist (etch mask) 477 is removed, and the cavities 478 shown in FIG. 6b can be lined with a barrier layer (not shown) and filled with metal such as Al, Cu, W, Ru, Co, or other conductive materials to form an upper gate contact 479. The barrier layer can prevent the metal 479 from atom migration and provide good adhesion to the metal 479. During M0 metallization, the upper gate region 493 and the lower gate region 492 are then connected to the first metal layer (M0). As can be seen in FIG. 6d, which is a front view of the semiconductor structure 400, a portion of the vertical element 470 (shown in FIG. 5a) is replace with the lower gate contact 475, and the lower gate contact 475 and is fully isolated from the upper gate region 493 by the spacer 474.

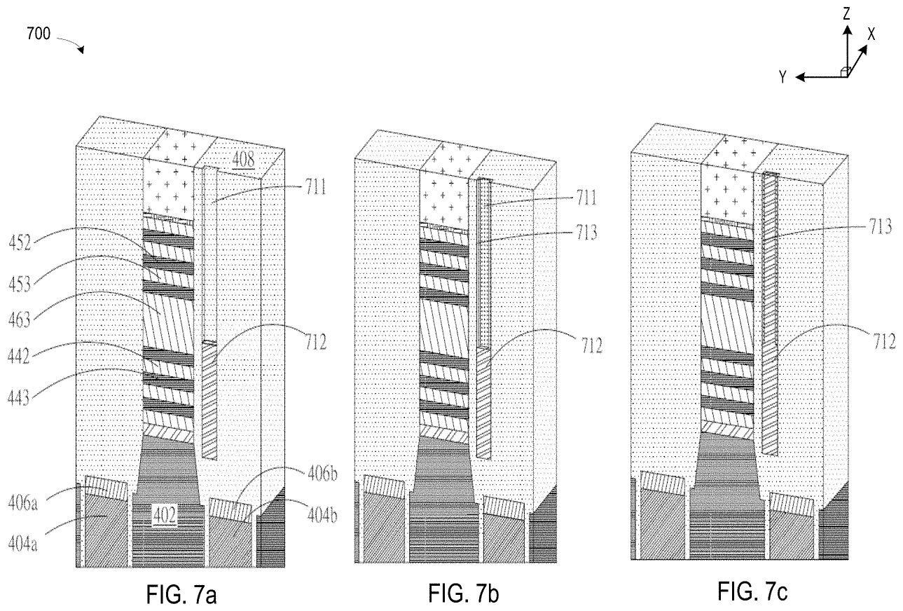

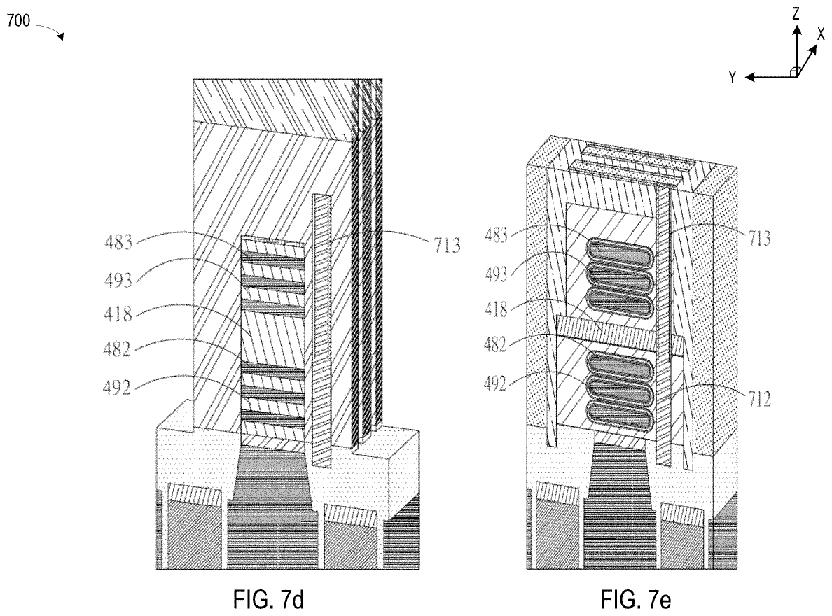

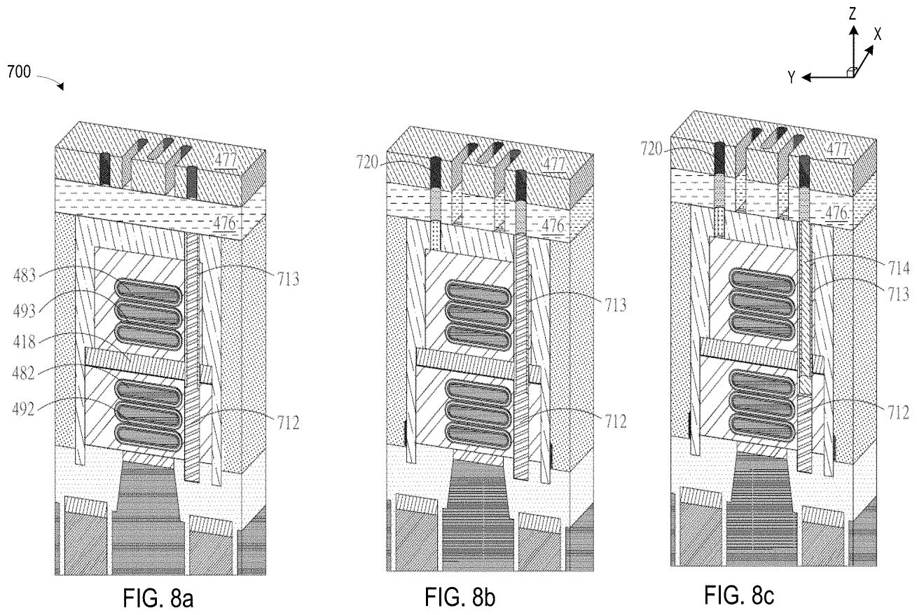

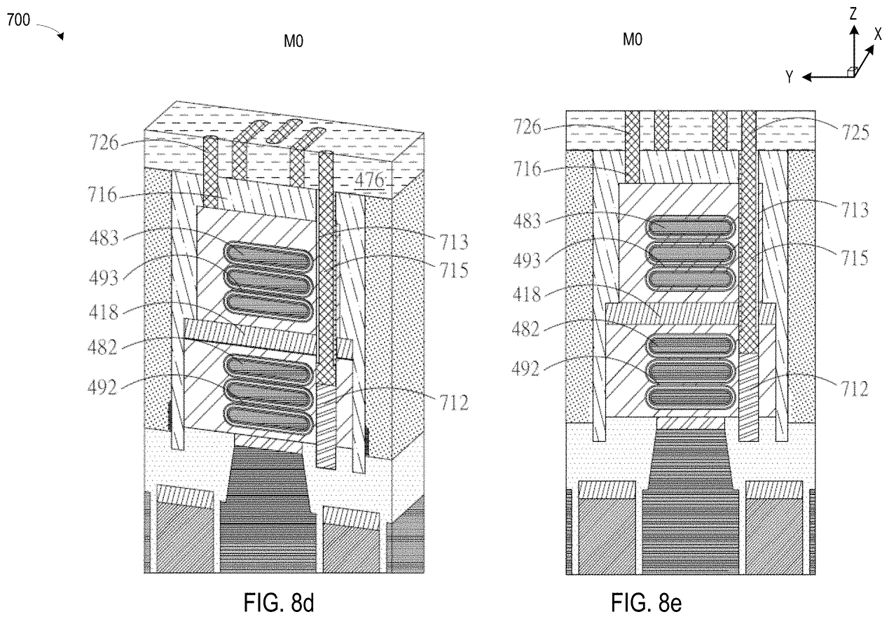

FIGS. 7a to 7e and 8a to 8e show cross-sectional substrate segments to illustrate another methods herein to achieve a 3D semiconductor structure 700 that has independent gate contacts according to some embodiments of the present disclosure. The method shown in FIGS. 7a to 7e and 8a to 8e differs from the method shown in 4a to 4f, 5a to 5e and 6a to 6d at least in that the spacer 474 shown in FIG. 5c inside the vertical element 470 is formed much earlier in the method, which is thus more robust and simpler than the previously described method. The method flow shown in FIGS. 7a to 7e and 8a to 8e also allows a true dual damascene process for M0 and the upper and lower gate contacts, that is, a single metallization step without any interfaces between M0 and the gate contacts.

As shown in FIG. 7a, which follows FIG. 4a, a lower gate contact opening 711 can be patterned and partially transferred down into the insulating layer 408 through an etching process until uncovering the lower semiconductor device tier (including the lower channel structure 442 and the lower insulating layer 443), and is filled with a dielectric material (or a sacrificial contact structure) 712 such as SiOC to a level at least lower than the upper semiconductor device tier (including the upper channel structure 452 and the upper insulating layer 453). The remaining lower gate contact opening 711 is lined with a spacer (e.g., a low-k spacer such as oxide) 713, as shown in FIG. 7b, and is filled with the dielectric material 712 again, as shown in FIG. 7c. As shown in FIGS. 7d and 7e, the RMG process is performed to form the lower source/drain (S/D) region 482, the lower gate region 492, the upper S/D region 483, the upper gate region 493 and the dielectric separation layer 418 of the semiconductor structure 700. FIG. 7e also shows that, after the SAC process is performed, the top of the dielectric material 712 and the oxide spacer 713 are uncovered. The dielectric material 712 is equivalent to the vertical element 470 and is used to form a lower gate contact of the semiconductor structure 700.

FIGS. 8a to 8e show the dual damascene process that is performed to connect the lower gate region 492 and the upper gate region 493 to the first metal layer (M0) in accordance with some embodiments of the present disclosure. As shown in FIG. 8a, the dielectric cap layer 476 is formed to cover the upper semiconductor device tier (including the upper S/D region 483 and upper gate region 493), and the resist (etch mask) 477 is patterned and formed on the dielectric cap layer 476. As shown in FIG. 8b, an etching process is performed to etch the dielectric cap layer 476 until uncovering the upper gate region 493 and the dielectric material 712 as well as the spacer 713 to form cavities 720. As shown in FIG. 8c, the dielectric material 712 is further etched (dry or wet) selectively with respect to the spacer 713 until to a level at the lower gate region 492 to form a cavity 714. As shown in FIG. 8d, the resist (etch mask) 477 is removed, and the cavities 720 and the cavity 714 shown in FIG. 8c can be filled with metal such as Al, Cu, W, Ru, Co, or other conductive materials to form the upper gate contact 716, an upper electrical connection 726, the lower gate contact 715, and a lower electrical connection 725 of the semiconductor structure 700. During M0 metallization, the upper gate region 493 and the lower gate region 492 are then connected to the first metal layer (M0). As can be seen in FIG. 8e, which is a front view of the semiconductor structure 700, a portion of the sacrificial contact structure 712 is replaced by the lower gate contact 715, and the lower gate contact 715 is fully isolated from the upper gate region 493 by the spacer 713.

Accordingly, the 3D semiconductor structure 400/700 can include the lower gate region 492, the upper gate region 493, the separation layer 418, the upper gate contact 479/716 and the lower gate contact 475/715. The upper gate region 493 can be vertically stacked on the lower gate region 492. The separation layer 418 can be disposed between and separate the upper gate region 493 and the lower gate region 492. The upper gate contact 716 can connect the upper gate region 493 to the upper electrical connection 726 at a first location above the upper gate region 493. The lower gate contact 715 can connect the lower gate region 492 to the lower electrical connection 725 at a second location above the upper gate region 493. The lower gate contact 715 can extend through the upper gate region 493 and be insulated from the upper gate region 493 by the spacer 713. In an embodiment, the lower gate contact 715 and the upper gate contact 716 are independent from each other. In another embodiment, the lower electrical connection 725 and the upper electrical connection 726 are independent from each other. In some other embodiments, the lower gate region 492 is a part of an n-type or p-type field effect transistor (FET), and the upper gate region 493 is a part of an n-type or p-type FET.

As can be appreciated, one skilled in the art understands that these embodiments are only examples of methods achieving the required final structure. Other methods and various combinations of techniques herein can provide a final structure. Independent bottom and top gate contacts are achieved with the contact connecting the first metal layer to the bottom gate without interfering with the top gate and without the need of complex patterning and metal etches.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the disclosure. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the disclosure. Such variations are intended to be covered by the scope of this disclosure. As such, the foregoing descriptions of embodiments of the disclosure are not intended to be limiting. Rather, any limitations to embodiments of the disclosure are presented in the following claims.

What is claimed is:

1. A method of manufacturing a three-dimensional (3D) semiconductor device, the method comprising:
forming a target structure, the target structure including a lower gate region, an upper gate region, and a separation layer disposed between and separating the lower gate region and the upper gate region;
forming a sacrificial contact structure extending vertically from the lower gate region through the separation layer and the upper gate region to a position above the upper gate region;
removing at least a portion of the sacrificial contact structure resulting in a lower gate contact opening extending from the position above the upper gate region to the lower gate region;
insulating a side wall surface of the lower gate contact opening; and
filling the lower gate contact opening with a conductor to form a lower gate contact.

2. The method of claim 1, further comprising:
depositing a lower gate stack material and an upper gate stack material in the lower gate region and the upper gate region, respectively.

3. The method of claim 2, further comprising forming an upper gate contact connected to the upper gate region.

4. The method of claim 3, wherein the upper gate contact and the lower gate contact are independent from each other.

5. The method of claim 3, further comprising forming an upper electrical connection connected to the upper gate contact, and a lower electrical connection connected to the lower gate contact.

6. The method of claim 5, wherein the upper gate contact, the upper electrical connection and the lower electrical connection are formed in a dual damascene process.

7. The method of claim 5, wherein the lower electrical connection and the upper electrical connection are independent from each other.

8. The method of claim 2, wherein depositing an upper gate stack material and a lower gate stack material is performed prior to removing at least a portion of the sacrificial contact structure.

9. The method of claim 8, prior to removing at least a portion of the sacrificial contact structure, further comprising:
performing a self-aligned-contact (SAC) process to form an SAC cap to cover the upper gate region.

10. The method of claim 8, prior to insulating a side wall surface of the lower gate contact opening, further comprising:
performing an isotropic etch to uncover the lower gate stack material of the lower gate region,
wherein insulating a side wall surface of the lower gate contact opening includes insulating a side wall surface of the lower gate contact opening and the uncovered lower gate stack material of the lower gate region.

11. The method of claim 2, wherein removing a portion of the sacrificial contact structure is performed prior to depositing an upper gate stack material and a lower gate stack material.

12. The method of claim 11, wherein filling the lower gate contact opening with a conductor includes:
filling the lower gate contact opening with a sacrificial contact material;
after depositing an upper gate stack material and a lower gate stack material is performed, removing the sacrificial contact material resulting in the lower gate contact opening; and
filling the lower gate contact opening with the conductor to form the lower gate contact.

13. The method of claim 1, wherein the lower gate region is a part of an n-type or p-type field effect transistor (FET), and the upper gate region is a part of an n-type or p-type FET.

14. The method of claim 1, wherein a bottom of the sacrificial contact structure is below the lower gate region.

15. The method of claim 1, wherein a bottom of the sacrificial contact structure is at a same level as the lower gate region.

16. The method of claim 1, wherein the upper gate region is vertically stacked on the lower gate region with the separation layer disposed therebetween.

17. A 3D semiconductor structure, comprising:
an upper gate region;
a lower gate region;
a separation layer disposed between and separating the upper gate region and the lower gate region;
an upper gate contact connecting the upper gate region to an upper electrical connection at a first location above the upper gate region; and
a lower gate contact connecting the lower gate region to a lower electrical connection at a second location above the upper gate region, the lower gate contact extending through the upper gate region and being insulated from the upper gate region,
wherein the lower gate contact and the upper gate contact are independent from each other.

18. The 3D semiconductor structure of claim 17, wherein the lower electrical connection and the upper electrical connection are independent from each other.

19. The 3D semiconductor structure of claim 17, wherein the upper gate region is vertically stacked on the lower gate region with the separation layer disposed therebetween.

20. The 3D semiconductor structure of claim 17, wherein the lower gate region is a part of an n-type or p-type field effect transistor (FET), and the upper gate region is a part of an n-type or p-type FET.
